(19) United States
(12) Patent Application Publication
(10) Pub. No.: US 2025/0276513 A1
(43) Pub. Date: Sep. 4, 2025

(54) MASK-PRINTING PROCESS WITH OPTIMIZED PARAMETERS, AND DEVICE

(71) Applicant: Siemens Aktiengesellschaft, München (DE)

(72) Inventors: Peter Frühauf, Falkensee (DE); Matthias Heimann, Potsdam (DE); Dirk Wormuth, Berlin (DE); Rene Blank, Berlin (DE); Stefan Nerreter, Heidesee OT Blossin (DE); Michael Erdmann, Borkheide (DE)

(21) Appl. No.: 18/858,785

(22) PCT Filed: Apr. 14, 2023
(86) PCT No.: PCT/EP2023/059778

§ 371 Date: Oct. 22, 2024

(30) Foreign Application Priority Data
Apr. 28, 2022 (EP) 22170422.4

(51) Int. Cl. B41F 33/00; B41F 15/08; B41F 15/36; B41M 1/12; B41M 1/26; G06T 7/00; H05K 3/12

(52) U.S. Cl. CPC B41F 33/0036; B41F 15/0818; B41F 15/36; B41F 33/0027; B41M 1/12; B41M 1/26; G06T 7/001; H05K 3/1225; G06T 2207/20081; G06T 2207/30144; H05K 2203/16

(57) ABSTRACT

For determining optimized parameter values of a mask-printing process, a quality value for the substrate is determined in a testing process following the printing operation, and an image of the upper side of the template is generated. A relationship between the parameter, the quality value and the template image are ascertained, and the relationship is used to determine an optimized value for the parameter. In the printing operation, the optimized value is set, and the printing process is monitored by using the respective template image, dispensing with the need for the testing process.

### CROSS-REFERENCE TO RELATED APPLICATIONS

This application claims priority to PCT Application No. PCT/EP2023/059778, having a filing date of Apr. 14, 2023, which claims priority to EP Application No. 22170422.4, having a filing date of Apr. 28, 2022, the entire contents both of which are hereby incorporated by reference.

### FIELD OF TECHNOLOGY

The following relates to a process for printing a substrate with a medium using a printing mask, and to a corresponding device.

### BACKGROUND

Mask-printing process denotes a printing process in which the material to be printed (substrate) is covered by a stencil or printing mask, and the medium to be printed is applied to the substrate through openings in the printing mask by a squeegee. For example, a screen or a plastic or metal stencil can be used as printing mask; hereinbelow, the term “stencil” is used for all types of printing masks. Various fields of application are known, for example it is possible to print color, lacquer or any other pasty medium onto the substrate. It is also used in the manufacture of electronic devices; a printed circuit board substrate in particular is printed with a solder material in order to be able to establish connections in the printed circuit board substrate or connections to electronics components.

In so doing, it is important that the pasty medium, i.e., the solder material for example, on the one hand essentially completely fills the openings (apertures) in the stencil but on the other hand does not protrude beyond the side of the stencil facing away from the substrate (stencil top side). Otherwise, the printing operation is defective, and the printed circuit board to be produced is also defective as a result: in the first case, desired electrical connections are not established; in the second case, there is a greater layer thickness than specified and the printed image becomes unclean, and also solder residue might remain on the stencil top side. Since solder residue interferes with the next printing operation, cleaning steps might optionally have to be performed.

The printing process is influenced by various parameters, for example the pressure and speed with which the squeegee is displaced over the stencil, or the speed at which the stencil is lifted off the substrate. In addition to such controllable parameters, which in principle can be set anew for each individual substrate, further parameters also influence the result, especially those that are conventionally set only once per production day or run (e.g., the alignment of the squeegee relative to the stencil), as well as those that are set once for a device type in a kind of setup (e.g., squeegee material, squeegee thickness, squeegee length, solder paste product) and those that represent design data (e.g., the thickness of the stencil, the arrangement and shape of the stencil openings). Furthermore, the term parameter also includes boundary conditions of the printing process that cannot be influenced or can only be influenced indirectly (e.g., temperature, humidity, vibrations, air pressure).

Errors can be minimized by the choice of suitable parameter values. For example, a layer thickness of the solder material that is too thick and remaining residue on the stencil top side can be largely avoided by way of suitable values for the squeegee pressure and a sufficiently parallel alignment of squeegee and stencil surface.

To check the print result, the prior art provides for implementation of what is known as a solder paste inspection (SPI) step. The printed substrate is removed from the printer chamber and examined optically. To this end, at least one image of the printed substrate is analyzed, for example by way of a direct comparison with a target image, or specific parameter values are ascertained, and the deviations from specified target values are ascertained. Certain characteristics such as e.g., the location in the x- and y-direction and the height are ascertained for a multiplicity of solder pads, and the percentage deviation from the target values is determined. Should a specified tolerance threshold be over-or undershot (i.e., in the event of a printing process error that is too large), the printed circuit board is discarded. In an alternative to that or in addition, an optical inspection is performed after further manufacturing steps (a so-called automated optical inspection, AOI).

It is also possible to optically examine the stencil bottom side (i.e., the side of the stencil facing the substrate) after the substrate has been lifted off, in order to recognize whether solder residue has remained in the apertures such that no solder pad was applied at the corresponding locations on the substrate.

These known processes are complicated and require relatively complex printer chambers or additional process stations in the production line. Further, although they can be used to determine that an error has arisen, they supply no information as to how the printing process needs to be modified in order to avoid the error in future. The latter requires an assessment by experts who, on account of their experience, recognize the way specific parameters of the printing operation can or must be modified in order to possibly eliminate the error.

### SUMMARY

An aspect relates to easily recognizing errors that have arisen in a mask-printing process and of developing an option for avoiding these errors.

Embodiments of the invention provide for a machine learning process to aid ascertainment of an optimized value for at least one parameter of a printing process. To this end, a printing operation is performed with an assigned value for the parameter, and an image of the top side of the stencil is recorded before and/or after the stencil is lifted off the substrate surface. A quality value is ascertained for the print result, i.e., for the printed substrate.

The printing operation is carried out anew with a modified value of the parameter, an image of the stencil top side is recorded before and/or after the stencil is lifted off, and the associated quality value of the print result is ascertained again. A relation, i.e., a relationship, between parameter, stencil image and quality value is ascertained in a machine learning process. The machine learning process is subsequently used to determine an optimized value of the parameter, i.e., a parameter value that leads to an improved quality value for the print result.

According to an exemplary embodiment, the printing operation is carried out multiple times with modified values of the parameter in each case and/or with modified values of further parameters in each case, an image of the stencil top side is created in each case, and a quality value is assigned to the respective print result. As a result, the machine learning process or the ascertained relationship between parameters and quality value becomes more reliable. On account of the ascertained relation between parameters and quality value, a computing unit can determine the correction measures that need to be performed in the event of a poor print result, i.e., determine the way specific parameters should be modified in order to increase the quality value.

By preference, the printed substrate is checked optically for the purpose of ascertaining the quality value. In the process, it is for example possible to compare an image of the printed substrate with a target image; in an alternative to that or in addition, the deviations, in particular percentage deviations, can be assessed for one or more specified characteristics (parameter values). The smaller these deviations, the higher the quality value. In the event of a plurality of characteristics, the deviations might optionally be weighted differently and combined with one another in a suitable fashion.

The process can be used in electronics manufacturing, wherein a printed circuit board substrate is used as substrate and an electrically conductive solder material is used as medium. In that case, the quality value can be ascertained with the aid of an SPI step. The printed substrate is optically evaluated in a conventional SPI station using a known process, by virtue of the deviation, in particular the percentage deviation, from corresponding target values being determined for one or more characteristics.

For example, the following controllable parameters can be used as parameters: squeegee speed, squeegee pressure, cleaning cycle, travel, lift-off speed (the stencil lifting off after the printing operation), off-contact distance (i.e., a possibly present distance between the stencil and the substrate).

In an alternative or in addition, the following parameters, for example, which are more or less controllable or selectable and/or represent boundary conditions of the process, can be used as parameters: relative alignment of the squeegee and stencil surface, squeegee material, squeegee thickness and length, batch number, type and manufacturer of the medium (paste), granularity of the metal particles, geometry of the apertures, thickness of the stencil, air temperature, humidity, vibrations, air pressure.

The stencil image can be recorded while the stencil still rests on the substrate. In embodiments, whether all apertures are filled with solder material or whether individual apertures are empty or only filled in part can be recognized in such an image.

In an alternative to that or in addition, the stencil image can be recorded after the stencil was lifted off from the substrate. In embodiments, whether solder material remained in the apertures post lift-off and hence was not printed, or only insufficiently printed, onto the substrate can be identified in such an image.

In both cases, whether solder material has remained on the stencil surface at locations without openings is recognizable.

The machine learning process allows ascertainment of complex relationships between parameters and quality values, identification of parameters that have a decisive influence on the result and determination of parameter values for an optimal result (this is referred to as the learning phase). A known optimization process can be used as machine learning process, for example Bayesian optimization. By including further parameters, an improved model with greater reliability can be created with the aid of the machine learning process.

Embodiments of the invention also comprise a process for producing a substrate printed with a medium, in which an optimal value is ascertained for at least one parameter for the printing process, and in which the relation between parameter and quality value is ascertained as described above. The learning phase can be integrated into this production process, i.e., the actual production of the printed circuit boards or, in general, of the printed substrate; in other words, the printed substrates produced during the learning phase can already represent the products to be produced. The required change in one or more parameter values is obtained by the fluctuations of the set parameter values which occur in practice, i.e., the modified value arises when the process is performed and is not firmly set.

In an exemplary embodiment, the production is implemented following the learning phase, in which an optimized value was ascertained for at least one parameter, as described above. Like in the learning phase, an image of the stencil top side before and/or after lift-off from the substrate is created during this production phase. The stencil image is used to monitor the printing operation and/or assess the printed substrate. As a result, larger and/or more targeted changes to the parameter values can be implemented in the learning phase, whereby the machine learning process supplies a faster and/or more reliable result.

Should the production phase follow the learning phase, the print result, i.e., the printed substrate, is not checked optically during the production phase; instead, an image of the top side of the stencil before and/or after lift-off from the substrate surface is created, like in the learning phase. The stencil image can be used to assign a quality value to the printing operation or the printed substrate since this relationship was learnt by the machine learning process during the learning phase. As a result, it is possible to manage without the SPI step during running production operation, or at least possible to not perform it after each printing operation. The stencil image can be used to ascertain the quality value of the printed substrate without performing an SPI step and/or an AOI step on the printed substrate. Production can be accelerated thereby, and the apparatus-related setup can be simplified.

The parameters can be set in automated fashion, and printed substrates with a specified quality value can be produced. In an alternative to that or in addition, it is possible to correct the set parameter value by way of an evaluation of the stencil image with the aid of the ascertained relation between parameter value, quality value and stencil image, i.e., it is possible to modify the set parameter value when errors occur and the quality drops, in such a way that the errors are reduced or avoided in subsequent printing operations.

The scope of embodiments of the invention includes continual or non-continual continuation of the learning process in the production phase, in order to further improve the model. In this case, in the production phase, the quality value of the created printed substrates is additionally ascertained and used for the machine learning process. As presented above, it is also possible to manage without a separate learning phase if the machine learning process is performed in the production phase.

Embodiments of the invention also comprise a device for carrying out the process. This device comprises a receiving device for the substrate to be printed, a holder for the stencil, a holder for a squeegee and an image recording device arranged such that it can record an image of the top side of the stencil after the printing operation was implemented. The image recording device is connectable to a computing unit such that created images of the stencil can be transmitted to the computing unit.

For example, the image recording device can be arranged on the housing or on the holder for the squeegee.

By preference, the device comprises a computing unit connected to the image recording device and connected to a testing unit. The computing unit is designed to store, for a printing operation, at least one image of the stencil post printing operation and a quality value ascertained by the testing unit and to ascertain a relation between these data. In this case, the quality value can also be ascertained by the computing unit, with the testing unit supplying data of the test result to the computing unit to this end.

The testing unit is a unit for an SPI step, which supplies an image of the printed substrate and/or data from an optical comparison between the printed substrate and a target image as test result.

### BRIEF DESCRIPTION

Some of the embodiments will be described in detail, with references to the following Figures, wherein like designations denote like members, wherein:

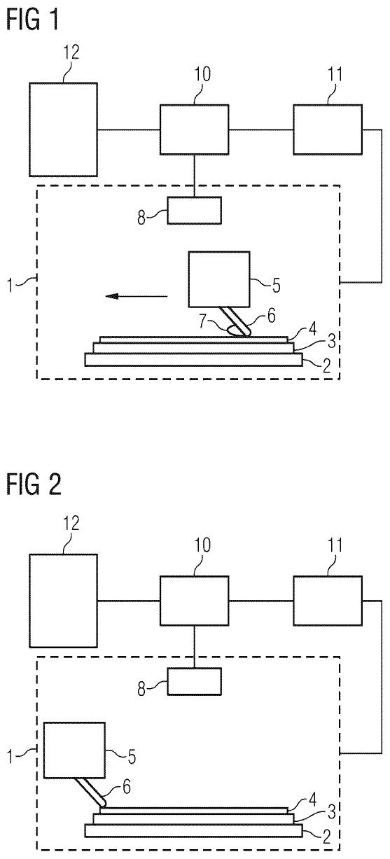

FIG. 1 shows a device for carrying out the process according to embodiments of the invention during and at the end of the printing operation;

FIG. 2 shows a device for carrying out the process according to embodiments of the invention during and at the end of the printing operation;

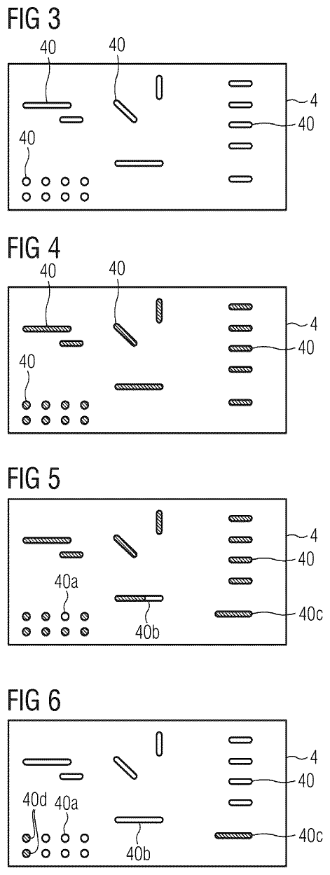

FIG. 3 shows an image of the stencil before the printing operation;

FIG. 4 shows an image of the stencil lying on the substrate at the end of the printing operation;

FIG. 5 shows an image of the stencil lying on the substrate at the end of a defective printing operation;

FIG. 6 shows an image of the stencil lifted off the substrate at the end of a defective printing operation; and

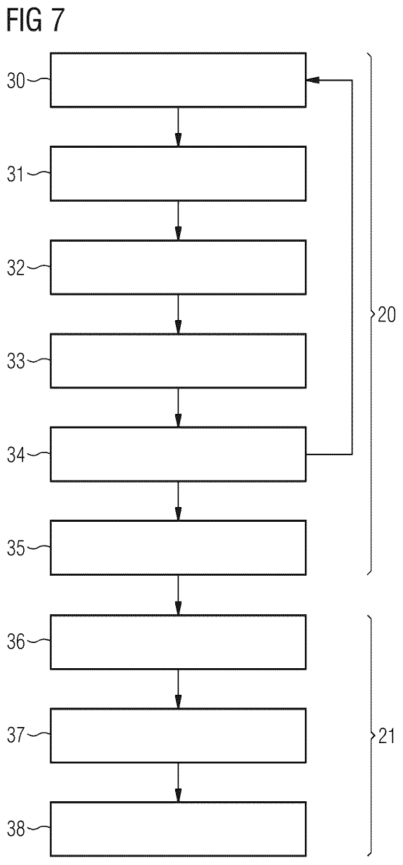

FIG. 7 shows a flowchart of the process.

### DETAILED DESCRIPTION

FIG. 1 schematically shows a chamber 1 of a stencil printer having a receiving device 2 for a printed circuit board substrate 3. A stencil 4 is arranged on the substrate surface by a holder (not depicted here). A squeegee apparatus comprises a holder 5 for a squeegee 6. During the printing operation, solder as medium 7 is applied over the surface of the stencil 4 by the squeegee 6; this is indicated by the arrow. In the process, openings in the stencil are filled with the solder.

Further, an image recording device 8 is arranged in the chamber in such a way that it can record the surface of the stencil 4.

A computing unit 10 is connected to the camera 8 such that images of the camera can be transmitted to the computing unit. Further, the computing unit 10 is connected to a control unit 11. On the one hand, the control unit controls the printing operation, for example by virtue of setting parameter values and controlling the movement of the squeegee unit. To this end, it receives data from the computing unit 10.

At least in the learning phase, the computing unit 10 is connected to a testing unit 12 in the form of an SPI station.

FIG. 2 shows the arrangement at the end of the printing operation; the squeegee has reached the end of the stencil 4. The camera 8 is now used to create an image of the stencil top side. In the exemplary embodiment, the stencil 4 lies on the substrate 3 when the recording is made; in an alternative to that or in addition, it is possible to record an image after the stencil was lifted off the substrate. The images are transmitted to the computing unit 10. The printed circuit board 3 printed with solder is moved into the testing unit 12 and tested there; in particular, an image of the substrate surface is recorded and parameter values ascertained therefrom (inter alia location, area and volume of the solder pad) are compared to target values. The resultant data, for example percentage deviations from target values, are transmitted to the computing unit 10, which determines a quality value therefrom.

FIG. 3 shows the surface of the stencil 4. It has openings 40 (apertures), through which medium is applied to the substrate surface during the printing operation. In this case, the thickness of the stencil corresponds to the thickness of the desired application.

FIG. 4 shows the image of the surface of the stencil 4, still located on the substrate, following the printing operation in the case of an error-free print. The apertures 40 are completely filled, and the squeegee has cleanly removed the solder from the stencil surface such that no solder residue is identifiable outside of the apertures.

FIG. 5 shows the image of the surface of the stencil 4, still located on the substrate, following the printing operation in the case of a defective print. Some apertures have not been filled (40a) or have not been filled completely (40b). For other apertures 40c, solder residue has remained on the stencil surface outside of the apertures.

FIG. 6 shows the image of the surface of the stencil 4, lifted off the substrate, following the printing operation in the case of a defective print corresponding to FIG. 3. Further defects have arisen due to the lift-off since solder material has remained stuck in the apertures 40d and 40c. Thus, the desired contacts have not been produced on the printed circuit board in this case. Then again, the fact that the opening 40a was not filled when squeegeeing, and hence there is also a defect there, cannot be identified from this image of the stencil. Thus, it is advantageous to create an image of the stencil surface before and after lift-off from the substrate, in order to reliably detect defects.

FIG. 7 schematically shows an exemplary embodiment of the process workflow. In a learning phase 20, a printing operation with preselected values for the parameters of the printing operation is carried out in step 30. For example, it is possible to select a squeegee material, a squeegee speed, a squeegee pressure and a stencil type. The control unit 11 stores the parameter values and controls the printing operation accordingly. After the print was completed, the control unit 11 controls the recording of the image of the stencil surface by the camera 8 (step 31); by preference, a respective image is recorded before and after the stencil 4 was lifted off the substrate 3. The images and associated parameter values are transmitted to the computing unit 10.

The printed substrate is analyzed in the testing station 12 in step 32; in particular, at least one image of the printed substrate is recorded, and the geometry of the print deposit or solder pad is measured within an SPI step. A quality value for the print result is ascertained, either in the testing station 12 or in the computing unit 10 following data transmission to the computing unit.

For example, percentage deviations from target values for position and thickness of the printed solder pads can be weighted and combined in order to calculate the quality value. The quality value, the stencil images and the utilized parameter values are stored in the computing unit in step 33.

The value of at least one parameter is modified in step 34. A printing operation with the modified parameter values is carried out, and described steps 30-34 are carried out in a loop until a sufficient amount of data is present. A machine learning process is applied in step 35 in order to ascertain the relation between parameters, stencil image and quality value from the data. With this, the learning phase 20 is complete.

Subsequently, the production phase 21 for producing printed substrates is performed. In step 36, the computing unit ascertains the optimal quality value and the associated parameter values and stencil images. The control unit performs the printing operation with these optimal parameter values (step 37). Following a printing operation, at least one stencil image is recorded in step 38 and a check is carried out as to whether this image corresponds to the expected optimal stencil image or is within a specified tolerance range. If deviations are too large, it is possible to perform suitable measures that were ascertained in the learning phase by machine learning or arise from the ascertained relation. In embodiments, the way specific parameters of the printing operation need to be modified, i.e., how the value thereof needs to be corrected in order to obtain the desired quality value, can be derived from the relation. It is possible to manage without an SPI step. However, a printed substrate can also continue to be analyzed by SPI, and the data obtained can be used for further improvement. Steps 37 and 38 are performed in a loop in order to print further substrates.

Although the present invention has been disclosed in the form of embodiments and variations thereon, it will be understood that numerous additional modifications and variations could be made thereto without departing from the scope of the invention.

For the sake of clarity, it is to be understood that the use of “a” or “an” throughout this application does not exclude a plurality, and “comprising” does not exclude other steps or elements.

### List of Reference Signs

1 Chamber

2 Receiving device

3 Printed circuit board substrate

4 Stencil

40a-d Apertures

5 Squeegee apparatus/holder

6 Squeegee

7 Solder

8 Camera

10 Computing unit

11 Control unit

12 Testing unit

20 Learning phase

21 Production phase

30-35 Steps of the learning phase

36-38 Steps of the production phase

1-9. (canceled)

10. A process for determining optimized parameter values of a printing process,
wherein a substrate to be printed is printed with a medium using a stencil,
the process comprising the following:
performing a printing operation with an assigned value for at least one parameter,
creating an image of a stencil top side before and/or after the stencil is lifted off a substrate surface,
ascertaining a quality value for the substrate printed during the printing operation,
performing the printing operation with a modified value for the at least one parameter,
following the printing operation with the modified parameter, once again creating an image of the stencil top side before and/or after the stencil is lifted off the substrate surface,
once again ascertaining an associated quality value for the substrate printed during the printing operation with the modified parameter,
ascertaining a relation between the at least one parameter, the quality value and the stencil image with an aid of a machine learning process, and
ascertaining an optimized value for the at least one parameter on the basis of the relation.

11. The process as claimed in claim 10, wherein the quality value is ascertained by optically checking the printed substrate.

12. The process as claimed in claim 10, wherein a printed circuit board substrate is used as the substrate and an electrically conductive soldering material is used as medium, and in that the quality value is ascertained by a solder paste inspection step.

13. The process as claimed in claim 10, wherein a squeegee speed, a squeegee pressure, a cleaning cycle, a travel, a lift-off speed of the stencil, a relative alignment of squeegee and stencil surface, a squeegee material, a batch number or a property of the medium, a geometric specification of the stencil openings and/or a thickness of the stencil is used as parameter.

14. A mask-printing process for producing a substrate on which a medium is printed, wherein a relation with a quality value and a stencil image as claimed in claim 10 is ascertained for at least one parameter,
wherein the optimized value for the at least one parameter is set,
wherein an image of the top side of the stencil is created before and/or after the stencil is lifted off the substrate surface,
wherein the stencil image is used to monitor the printing process and/or assess the printed substrate.

15. The mask-printing process as claimed in claim 14, wherein the at least one parameter is initially set to one value for the ascertainment of the relation of the at least one parameter with the quality value, and the modified value for the at least one parameter arises from parameter fluctuations.

16. The mask-printing process as claimed in claim 10, wherein the set value for the at least one parameter is corrected following an evaluation of the stencil image.

17. A device for carrying out the process as claimed in claim 10, comprising:
a receiving device for the substrate,
a holder for the stencil,
an image recording device arranged such that the image recording device can record an image of the top side of the stencil after the printing operation was implemented.

18. The device as claimed in claim 17, further comprising a computing unit connected to the image recording unit and to a testing unit, wherein the computing unit is configured to ascertain, within a scope of a machine learning process, a relation between at least one parameter of a printing operation, a quality value assigned to the printed substrate with the aid of the testing unit and the image of the stencil recorded after the printing operation.

19. The process, mask-printing process, as claimed in claim 10, wherein printing operations with modified parameters are carried out in a loop in order to obtain a sufficient amount of data to perform the machine learning process, and the relation is ascertained by the machine learning process from the data.

20. The process, mask-printing process, as claimed in claim 10, wherein the optimized value for the parameter is ascertained on a basis of suitable measures that were ascertained in a learning phase by the machine learning process or arise from the relation ascertained with an aid of the machine learning process.

21. The process, mask-printing process, as claimed in claim 10, wherein in order to ascertain the optimized value, the way specific parameters of the printing operation need to be corrected in order to obtain a desired quality value is derived from the relation.

22. The process, mask-printing process, as claimed in claim 10, wherein the images of the stencil top side are created before and after the stencil is lifted off the substrate surface.
